(19) United States
(12) Patent Application Publication
(10) Pub. No.: US 2007/0184612 A1
(43) Pub. Date: Aug. 9, 2007

(54) Method for assembling a panel for an LCD

(75) Inventors: Chia-Hao Chan, Kuei Shan Shiang (TW); Ju-Yu Lee, Kuei Shan Shiang (TW); Chin-Sung Lin, Kuei Shan Shinag (TW); Chwan-Jye Lin, Kuei Shan Shiang (TW)

Correspondence Address: BACON & THOMAS, PLLC, 625 SLATERS LANE, FOURTH FLOOR, ALEXANDRIA, VA, 22314, US

(73) Assignee: Quanta Display Inc., Kuei Shan Hsiang (TW)

(21) Appl. No.: 11/702,192

(22) Filed: Feb. 5, 2007

(30) Foreign Application Priority Data
Feb. 7, 2006 (TW) 095104000

(51) Int. Cl. H01L 21/336

(52) U.S. Cl. 438/257

(57) ABSTRACT

A method for assembling a liquid crystal display includes providing a thin-film-transistor substrate and a color-filter substrate having an active area and a non-active area, wherein plural spacers are formed in the in the active area of the color-filter substrate. At least two spacing-pads are individually formed in the surrounding non-active area at different locations adjacent to the edge of the active area, and the top of the spacing-pad is as high as the spacer in the active area. The color-filter substrate and the thin-film-transistor substrate are sealed.

### BACKGROUND OF THE INVENTION

1. Field of the Invention

The present invention relates to a panel assembling method for an LCD device, and more particularly, to a panel assembling method for reducing the “mura” phenomenon in the forbidden area of the panel.

2. Description of Related Art

The manufacturing process of a thin film transistor liquid crystal display (TFT-LCD) is divided into three parts: substrate-manufacturing, panel-assembling, and module-fabricating. The substrate-manufacturing and the panel-assembling are the initial stages of the manufacturing process of a panel, whereas the module-fabricating completes the assembly of an LCD module by mounting a backlight module and driving circuits on the panel. The substrate-manufacturing can be further divided into two parts the manufacturing of the TFT substrate and that of the color filter (CF) substrate.

During the panel-assembling, a plurality of spacing materials (i.e. spacers) are usually used to maintain a cell gap between two substrates for filling with liquid crystal molecules. The liquid crystal molecules are able to be rotated and aligned in the cell gap. The height of the spacers is closely pertinent to the cell gap of the panel and the graphic quality. Thus, the diameters and the grain sizes of the spacers must be distributed uniformly so as to meet the requirement of high accuracy. Besides, the spacers can be formed on the surfaces of the TFT substrate or CF substrate.

The CF substrate having photo spacers is the key component for the highly-bright, highly-transmitted and large-sized TFT LCD and further critically affects various properties of the TFT LCD. Generally, among the techniques for manufacturing the CF substrates having photo spacers, the technique preparing the spacers by a photolithographic process is the best one to achieve the accuracy required by the industry and the optimal display quality as a whole.

However, during the photolithographic process for preparing photo spacers on a CF substrate, two gap sensor windows must be prearranged on the applied mask having patterns of spacers in the regions corresponding to the non-active areas in order to align the mask and the substrate accurately during exposing. Referring to the top view of FIG. 1, the photo spacers are not formed in the window regions 05, 06 that are called “forbidden areas”. To prevent the photo spacers from being formed in the forbidden areas 05, 06, the regions corresponding to the forbidden areas 05, 06 on the mask (not shown) having patterns of spacers are carved out, and the forbidden areas 05, 06 are masked by another shield 50 during the photolithographic process. A negative-type photoresist is coated on the substrate, after the substrate is exposed with the mask having patterns of spacers and forbidden areas 05, 06, patterns are not formed in non-exposed regions. In other words, the photo spacers are not formed in the forbidden areas masked by shield 50.

Referring to FIG. 2, a cross-section view for illustrating the process for preparing spacers on a CF substrate by a photolithographic process is shown. First, as shown in FIG. 2(a), a negative-type photoresist layer 30 is coated over a glass substrate 00 having RGB pixels 01, a black matrix layer 02, a planarizing layer 10, and a transparent electrode 20 to cover the transparent electrode 20. Then exposure and development are proceeded by using a mask 40 which has the pattern of the photo spacers and a shield 50 which masks the forbidden regions, so that photo spacers 80 are formed in the regions exposed to light. As shown in FIG. 2(b), after the photoresist 80 is removed, a plurality of photo spacers having predetermined height are formed on the transparent electrode 20, and there is no photo spacer formed in the forbidden areas of the CF substrate at the same time.

In the following process, when a single CF substrate is cut and adhered to a TFT substrate, due to the lack of support by photo spacers in the forbidden area, the pressure sustained by the forbidden area is different from that of areas having photo spacers, which tends to result in the “mura” phenomenon in the vicinity of the forbidden area. “Mura” is the transliteration of a Japanese word meaning unequal pressure on the panel of the display device that causes uneven brightness and various marks, which are similar to ripples. Referring to FIG. 3, ripple 60 is formed in the active area after assembly of panel 70, and therefore the display effects are affected. The manufacturer has to categorize the panels having mura phenomenon as defected products, and the defected products result in losses of cost for the panel manufacturer. In view of this problem, there is a need for method to avoid the mura phenomenon occurring in the forbidden area of the panel during assembly of panels with CF substrates and TFT substrates, especially the CF substrates prepared by a photolithographic process.

### SUMMARY OF THE INVENTION

The object of the present invention is to provide a method for assembling a panel for an LCD, which can prevent the mura phenomenon from forming in assembled panels and thus improve the yield.

The steps of the present invention comprise: (a) providing a thin-film-transistor substrate and a color-filter substrate, wherein the color filter substrate comprises a non-active area, and an active area having plural spacers formed in the active area of the color-filter substrate, at least two spacing-pads are individually formed in two opposite regions close to an edge of the active area and in a corresponding periphery of the non-active area adjacent to the edge of the active area, and the height of the spacing-pads is as same as those of the spacers in the active area; and (b) sealing the color-filter substrate and the thin-film-transistor substrate.

Preferably, the present invention can comprise a step (c) after step (b), i.e., depositing a liquid crystal in the panel. Meanwhile, the assembled color filter can further comprise a plurality of pixel units and at least one electrode structure, and the thin-film-transistor substrate is preferably comprises a transparent electrode.

The present invention further comprises a method to prepare a color filter substrate having spacing-pads, the steps comprising: (a) providing a color filter substrate having an active area and a non-active area; and (b) forming plural spacers in the active area, and forming the at least two spacing-pads individually in the surrounding non-active area; wherein the at least two spacing-pads are individually formed in two opposite regions close to an edge of the active area and in a corresponding periphery of the non-active area adjacent to the edge of the active area, and the height of the spacing-pads is as same as those of the spacers in the active area.

The present invention also discloses a color filter substrate, comprising: an active area having a plurality of photo spacers; a non-active area having at least two spacing-pads; wherein at least two spacing-pads are individually formed in two opposite regions close to an edge of the active area and in a corresponding periphery of the non-active area adjacent to the edge of the active area, and the height of the spacing-pads is as same as those of the spacers in the active area.

In the present invention, there is no particular limitation to the material forming photo spacers and spacing-pads, but it is preferably a photoresist, and more preferably a negative photoresist. There is no particular limitation to the method for forming the color filter of the present invention; however, to achieve the required accuracy of the photo spacers, it is preferable to be prepared by a photolithographic process. In addition, the photolithographic process is preferably performed in conjunction with a mask having a pattern of photo spacers and spacing-pads. There is no particular limitation to the pattern of spacing-pads in the present invention, but it is preferable to be patterns that can be formed in accordance with the exposure-target zone of the mask, such as a rectangle, a circle or a U-shape.

In the color filter substrate of the present invention, the tops of the spacing-pads are as high as those of the photo spacers in the active area, but the forming materials can be the same or different. When the surfaces of the active area and non-active area are at the same plane, the photo spacers and spacing-pads formed on the surfaces have the same height and thickness, so as to uniformly sustain the pressure of adhering TFT substrate; however, when the surfaces of the active area and non-active area are at different planes, it is preferable to form photo spacers and spacing-pads having different thicknesses in order to have the tops of photo spacers and spacing-pads formed in the active area and the non-active area.

To enable the color filter to evenly sustain the adhering pressure from the TFT substrate, the spacing-pads are preferably formed at two sites opposite to each other on the edge of the non-active area, so that the pressure is evenly distributed. In other words, the spacing-pads are individually formed in two opposite regions close to an edge of the active area and in a corresponding periphery of the non-active area adjacent to the edge of the active area. Because the main purpose to form the spacing-pads is to uniformly distribute the adhering pressure of the substrates, the shapes of the spacing-pads are irrelevant to their function, as long as the tops of the spacing-pads and photo spacers are at the same plane, but they are preferably rectangles, circles or U-shapes.

The present invention forms spacing-pads on the edge of the non-active area when forming photo spacers on a substrate; the spacing-pads serve as supports of the forbidden area during assembly of the panel to distribute the adhering pressure, so the above-mentioned mura phenomenon can be substantially reduced.

Other objects, advantages, and novel features of the invention will become more apparent from the following detailed description when taken in conjunction with the accompanying drawings.

### BRIEF DESCRIPTION OF THE DRAWINGS

FIG. 1 is a top view of a CF substrate having a forbidden area;

FIGS. 2(a) and 2(b) are cross-section views of the process for preparing photo spacers on the CF substrate;

FIG. 3 illustrates a panel showing the mura phenomenon after the CF substrate having a forbidden area is sealed with a TFT array substrate;

FIG. 4 is a top view of a CF substrate in a preferable embodiment of the present invention;

FIGS. 5(a) and 5(b) are cross-section views of the process for preparing photo spacers on the CF substrate of a preferable embodiment of the present invention;

FIG. 6 illustrates that a panel assembled by sealing a CF substrate with a TFT array substrate shows no mura phenomenon; and

FIG. 7 is a top view of the CF substrate of another preferable embodiment of the present invention.

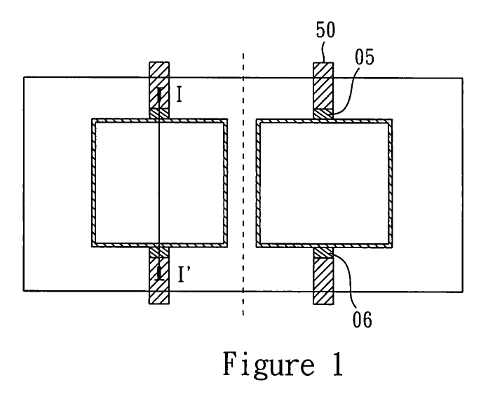

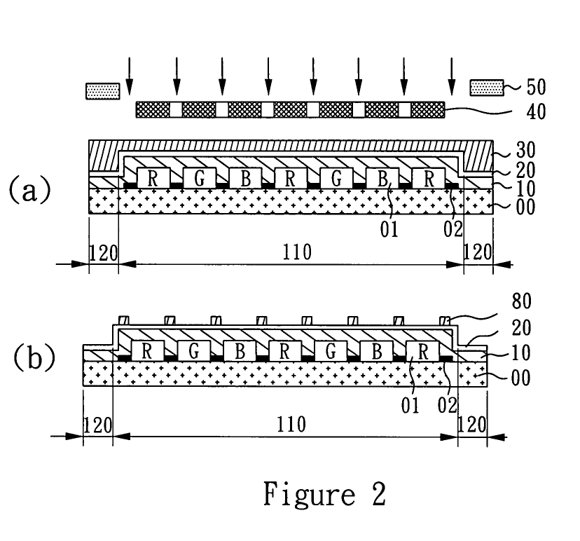

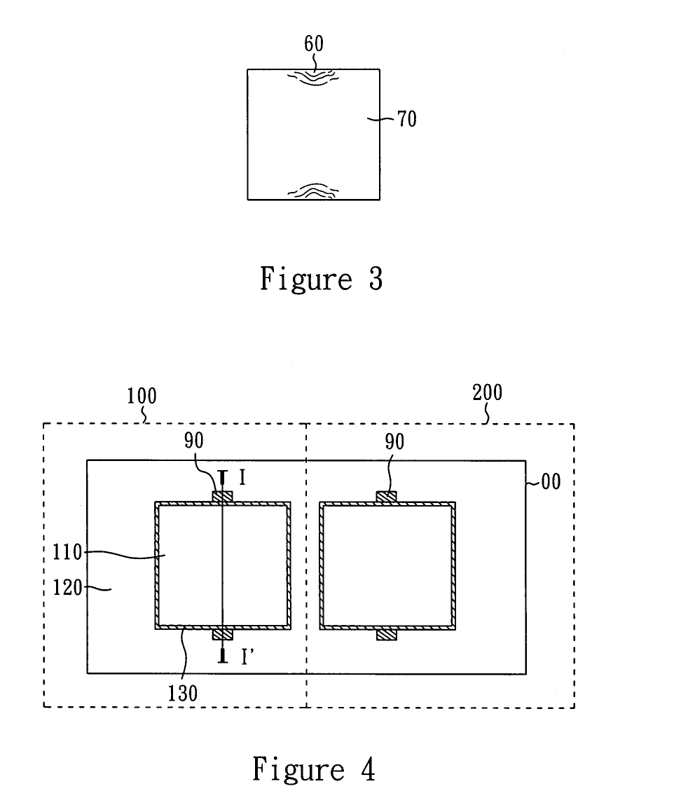

### DETAILED DESCRIPTION OF THE EMBODIMENT

### EXAMPLE 1

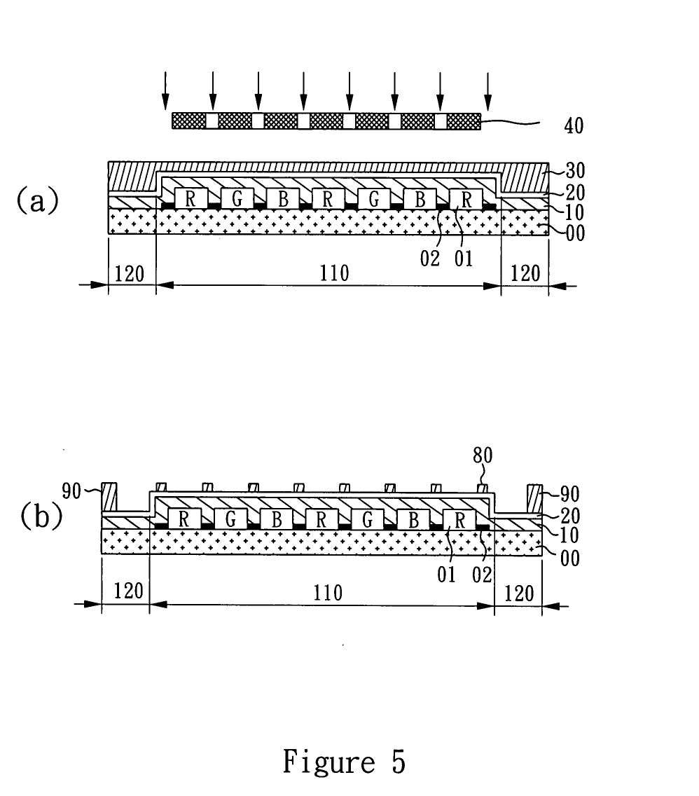

Please refer to FIG. 4 and FIG. 5 showing the process to prepare photo spacers on a color filter substrate to illustrate one of the technical features of the present invention.

First, the area of a color filter substrate is defined on a glass substrate 00. As shown in FIG. 4, two areas for color filters substrate 100, 200 are defined by the broken lines on a large substrate 00. An active area 110 and a non-active area 120 are further defined on the color filter 100. A contact area 130 is retained at the border between the active area 110 and the non-active area 120, or the periphery of the non-active area 120, to facilitate the sealing with a TFT substrate in the subsequent process.

FIG. 5 illustrates a cross section view along the I-I′ line of the color filter 100, the photolithographic process is performed on the substrate 00.

Referring to FIG. 5(a), a negative-type photoresist 30 is coated over the glass substrate 00 having RGB pixels 01, a black matrix layer 02, a planarizing layer 10 and a transparent electrode 20. The negative-type photoresist 30 covers the transparent electrode 20 fully. The negative-type photoresist 30 is exposed to UV light through the mask 40 having a pattern of photo spacers. The shield 50 normally used to mask the forbidden areas is absent from this step.

After exposure and development, photo spacers 80 are formed on the areas exposed to light, as shown in FIG. 5(b). A plurality of photo spacers having a predetermined height are formed on the transparent electrode 20 after stripping. The mask used in the photolithography process has carved-out regions, through which the negative-type photoresist 30 is exposed directly to the UV light, and the spacing-pads 90 are formed in the forbidden areas that correspond to the carved-out regions. The height of the spacing-pads 90 is the same as those of the photo spacers formed in active area 110, and the position of the spacing-pads 90 is in two opposite regions close to an edge of the active area 110 and in a corresponding periphery of the non-active area 120 adjacent to the edge of the active area 110.

After the photo spacers on the CF substrate are prepared, a TFT array substrate is sealed with the CF substrate along the contact region 130 for sealant, as shown in FIG. 4. Spacing-pads 90 are formed in the forbidden areas and are as high as the photo spacers in active area 110 to result in equal or nearly equal pressure upon sealing of upper and lower substrate.

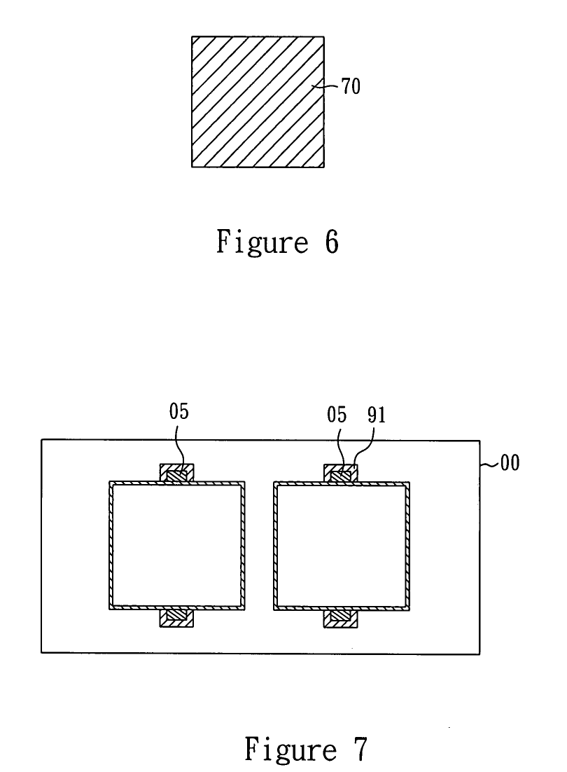

After the upper and the lower substrates are sealed, the part of the non-active area of the CF substrate is cut off to leave the part of the active area of the CF substrate only. The fabricating process of a panel by combining a TFT substrate and a CF substrate having spacing-pads can reduce the problems of uneven adhesion pressure as well as the “mura” phenomenon. The result shown in FIG. 6 indicates that the original areas that mura phenomenon normally appears are eliminated after the fabricating process described above is completed.

### EXAMPLE 2

The method of example 1 shows the spacing-pads 90 formed in non-active area 120 of the CF substrate 100 to avoid the mura phenomenon occurring after panel assembly. Another embodiment is illustrated in this example with FIG. 7, and the purpose of mura phenomenon avoidance in the forbidden area is achieved as well.

As shown in FIG. 7, a spacing washer 91 is formed along the edge of the forbidden area, and the steps to form the spacing washer 91 are similar to the steps disclosed in Example 1 above, except that the mask further comprises a pattern corresponding to the U-shape washer used in the present example.

The feature of the present invention as described above is that the shield originally used to cover the forbidden area during the photolithographic process is completely absent. Hence, a large-area of spacing-pads or washings will be formed in the partial forbidden area where no photo spacers is not formed in the prior art. Likewise, other patterns forming the spacing-pads having the same heights as those of the photo spacers could be utilized in the present invention, and it is expected that the mura phenomenon could be prevented after panel assembly as described in Example 1.

The method disclosed in the present invention can prevent occurrence of the mura phenomenon resulting from an unequal gap distance of the panel due to uneven pressure. Hence, the display quality of the panel is thus improved, the yield is enhanced and the cost of the panel manufacturer is lowered as well.

Although the present invention has been explained in relation to its preferred embodiment, it is to be understood that many other possible modifications and variations can be made without departing from the scope of the invention as hereinafter claimed.

What is claimed is:

1. A method for assembling a panel of a liquid crystal display device, comprising the following steps:
a) providing a thin-film-transistor substrate and a color-filter substrate, wherein the color filter substrate comprises a non-active area, and an active area having plural spacers formed in the active area of the color-filter substrate, at least two spacing-pads are individually formed in two opposite regions close to an edge of the active area and in a corresponding periphery of the non-active area adjacent to the edge of the active area, and the height of the spacing-pad is as same as those of the spacers in the active area; and
b) sealing the color-filter substrate and the thin-film-transistor substrate.

2. The method of claim 1, wherein the materials of the spacers and spacing-pads are photoresist.

3. The method of claim 1, wherein the color-filter substrate is formed by a photolithographic process.

4. The method of claim 3, wherein the photolithographic process is performed with a mask having a pattern of photo spacers and spacing-pads.

5. The method of claim 1, wherein the thickness of the spacers and that of the spacing-pads is different.

6. The method of claim 1, wherein the spacing-pads are formed at two sites opposite to each other on the edge of the non-active area.

7. The method of claim 1, wherein the shape of the spacing-pads is in a shape of a rectangle, a circle or a U-shape.

8. The method of claim 1, further comprising a step (c) after step (b), of depositing a liquid crystal in the panel.

9. The method of claim 1, wherein the color-filter substrate further comprises a plurality of pixel units and at least one electrode structure.

10. The method of claim 1, wherein the thin-film-transistor substrate comprises a transparent electrode.

11. A method for preparing a color filter substrate having spacing-pads, the steps comprising:
(a) providing a color-filter substrate having an active area and a non-active area; and
(b) forming plural spacers in the active area, and forming at least two spacing-pads individually in the surrounding non-active area;
wherein the at least two spacing-pads are individually formed in two opposite regions close to an edge of the active area and in a corresponding periphery of the non-active area adjacent to the edge of the active area, and the height of the spacing-pads is as same as those of the spacers in the active area.

12. The method of claim 11, wherein the wherein the materials of the spacers and spacing-pads are photoresist.

13. The method of claim 11, wherein the spacers and spacing-pads are formed by a photolithographic process.

14. The method of claim 13, wherein the photolithographic process is performed in conjunction with a mask having a pattern of photo spacers and spacing-pads.

15. The method of claim 11, wherein the thickness of the spacers and that of the spacing-pads is different.

16. The method of claim 11, wherein the spacing-pads are formed at two sites opposite to each other on the edge of the non-active area.

17. The method of claim 11, wherein the spacing-pads are in a shape of a rectangle, a circle, or U.

18. A color-filter substrate having spacing-pads, comprising:
an active area having a plurality of photo-spacers; and
a non-active area having at least two spacing-pads; wherein the at least two spacing-pads are individually formed in two opposite regions close to an edge of the active area and in a corresponding periphery of the non-active area adjacent to the edge of the active area, and the height of the spacing-pads is as same as those of the spacers in the active area.

19. The color-filter substrate of claim 18, wherein the materials of the spacers and spacing-pads are photoresist.

20. The color-filter substrate of claim 18, wherein the thickness of the spacers and that of the spacing-pads is different.

21. The color filter substrate of claim 18, wherein the spacing-pad are formed at two sites opposite to each other on an edge of the non-active area.

22. The color filter substrate of claim 18, wherein the spacing-pads are in a shape of a rectangle, a circle, or U.
